(19) United States
(12) Patent Application Publication
(10) Pub. No.: US 2008/0160429 A1
(43) Pub. Date: Jul. 3, 2008

(54) METHOD FOR MANUFACTURING A PHOTOMASK

(75) Inventor: Goo Min Jeong, Chungcheongbuk-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyeonggi-do (KR)

(21) Appl. No.: 11/771,134

(22) Filed: Jun. 29, 2007

(30) Foreign Application Priority Data
Dec. 29, 2006 (KR) 10-2006-0138847

(51) Int. Cl. G03F 1/00

(52) U.S. Cl. 430/5

(57) ABSTRACT

A method for manufacturing a photomask includes forming a resist pattern on a substrate with a light blocking layer formed thereon, etching the light blocking layer using the resist pattern as a mask, measuring a critical dimension (CD) of the resist pattern, irradiating ultraviolet rays on the resist pattern to modify the CD of the resist pattern, thereby forming a CD-modified resist pattern, and etching the light blocking layer using the CD-modified resist pattern.

### CROSS-REFERENCE TO RELATED APPLICATION

Priority to Korean patent application number 10-2006-0138847, filed on Dec. 29, 2006, the disclosure of which is incorporated by reference in its entirety, is claimed.

### BACKGROUND OF THE INVENTION

The invention relates to a method for manufacturing a photomask and, more particularly, to a method for manufacturing a photomask capable of improving uniformity of a critical dimension (CD) of a pattern formed on the photomask using ultraviolet rays.

Various patterns of semiconductor devices are formed using photolithography technology. Along with the trend of highly integrated, high density semiconductor devices, various techniques for forming a finer pattern have been developed. Many studies have been performed on an exposure method using an electron beam, an ion beam, X rays, a modified illumination method diffracting light from a light source, new resist materials, resist processing methods, and the like. In addition to the miniaturization of semiconductor devices, the accuracy and uniformity of the critical dimension (CD) of the photomask pattern have become more important as the design rule of semiconductor devices have become more stringent.

In a conventional method to enhance the CD uniformity of photomask patterns, the mask is exposed to an electron beam and, then, the CD uniformity of the pattern is checked using a scanning electron microscope (SEM). If a defect is detected, the mask under manufacture is rejected and a new mask is reproduced once the exposure conditions of the electron beam are appropriately reset. However, the conventional method depends mainly on the engineer's experience. Thus, although the exposure conditions are controlled, it cannot be predicted how much the CD uniformity of the photomask pattern will be improved. Since a photomask should be reproduced, the manufacturing period is extended and a manufacturing costs are increased. Moreover, it is difficult to improve the uniformity using an electron beam exposure apparatus and subpar exposure steps result.

### BRIEF SUMMARY OF THE INVENTION

An aspect of the invention provides a method for manufacturing a photomask including; forming a resist pattern over a substrate with a light blocking layer formed thereon; etching the light blocking layer using the resist pattern as a mask; measuring a critical dimension (CD) of the resist pattern; irradiating ultraviolet rays on the resist pattern to modify the CD of the resist pattern, thereby forming a CD-modified resist pattern; and etching the light blocking layer using the CD-modified resist pattern.

The step of measuring the critical dimension (CD) of the resist pattern preferably includes: measuring the CD of the resist pattern in multiple mask regions of the resist pattern; obtaining a variation between the measured CD and a designed CD of the resist pattern in the multiple mask regions; and making a map based on the obtained variation according to the multiple mask regions.

In the step of irradiating ultraviolet rays on the resist pattern to modify the CD of the resist pattern, an irradiation amount of the ultraviolet rays preferably varies according to the multiple mask regions based on the map.

In the step of irradiating ultraviolet rays on the resist pattern to modify the CD of the resist pattern, the ultraviolet rays are preferably irradiated on the resist pattern until the CD of the resist pattern is equal to a designed CD of the resist pattern.

### BRIEF DESCRIPTION OF THE DRAWINGS

The above and other objects, features, and advantages of the invention will be more clearly understood from the following detailed description taken in conjunction with the accompanying drawings, in which:

FIGS. 1 to 2 show cross sectional views illustrating the resulting CD variation in a resist pattern formed by irradiation with ultraviolet rays;

FIGS. 3 to 5 are scanning electron microscope (SEM) photographs illustrating the CD variation in a resist pattern based on the amount of ultraviolet radiation, which variation is observed after the resist pattern is formed in an isolated pattern;

FIGS. 6 to 8 show cross sectional views illustrating a method for manufacturing a photomask according to the invention.

FIG. 9 shows a map representing the variation between the measured CD and the designed CD of the pattern according to the various mask regions.

### DETAILED DESCRIPTION OF THE INVENTION

Preferred embodiments of the invention will now be described in detail with reference to the accompanying drawings. These embodiments are used only for illustrative purposes, and the invention is not limited thereto.

The invention provides a method for improving the uniformity of the critical dimension (CD) of a pattern, wherein after a phase shift layer, a light blocking layer, and a resist are sequentially formed and the resist is exposed to an electron beam, the light blocking layer and the phase shift layer are etched using a resist pattern, and the CD of the resist pattern is controlled using ultraviolet rays. The pattern can include regions having different pattern dimensions by controlling the amount of ultraviolet radiation according to the various regions.

The following steps are performed to evaluate the CD variation based on to the amount of ultraviolet radiation.

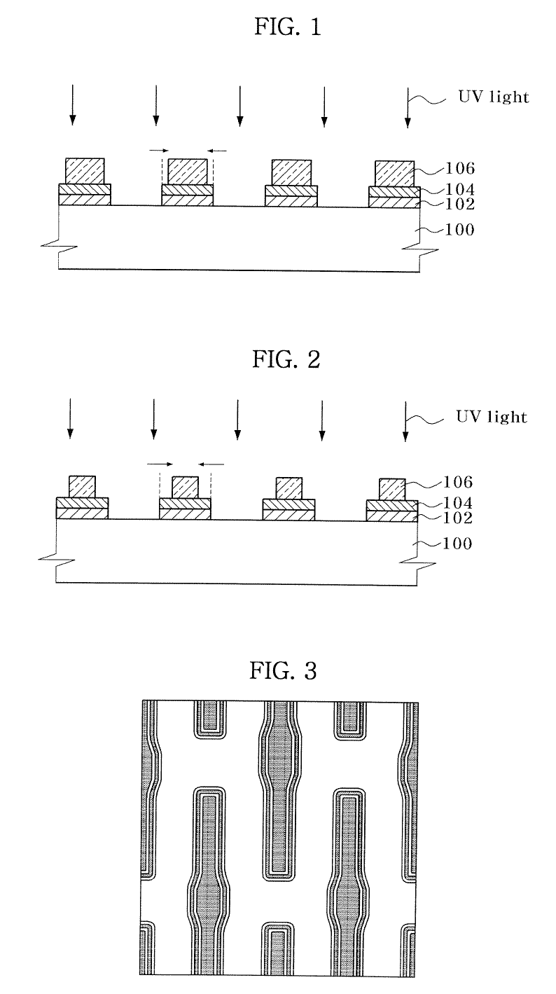

Referring to FIGS. 1 and 2, a phase shift layer 102 formed of, for example, a molybdenum silicon nitride (MoSiN) film, a light blocking layer 104 formed of, for example, a chromium (Cr) film and an electron beam resist 106 are uniformly coated on a transparent substrate 100 such as quartz, so that a blank mask is prepared. The resist 106 is exposed to an electron beam and the exposed resist 106 is developed and hardened to form a resist pattern. The light blocking layer 104 and the phase shift layer 102 are sequentially etched using the resist pattern as a mask.

Then, the CD of the resist pattern is observed while the patterned resist 106 is irradiated with ultraviolet rays having a wavelength of about 172 nm for a predetermined time period. It can be seen that the CD of the resist pattern decreases as the irradiation time of ultraviolet rays increases. In particular, it can be seen that there is a significant decrease in the width as opposed to the height of the resist pattern.

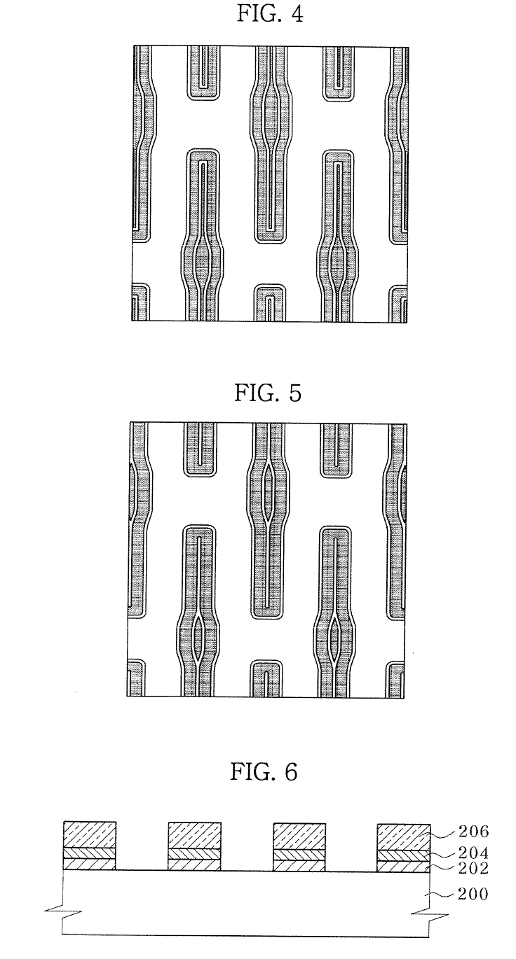

FIGS. 3 to 5 are scanning electron microscope (SEM) photographs showing the CD variation of the resist pattern based on the amount of ultraviolet radiation, which variation is observed after the resist pattern is formed in an isolated pattern. FIG. 3 is an SEM photograph obtained when the resist pattern was irradiated with ultraviolet rays having a wavelength of about 172 nm for 20 minutes. FIG. 4 is an SEM photograph obtained when the resist pattern was irradiated with ultraviolet rays having a wavelength of about 172 nm for 50 minutes. FIG. 5 is an SEM photograph obtained when the resist pattern was irradiated with ultraviolet rays having a wavelength of about 172 nm for more than 50 minutes. As can be seen from the photographs, when the resist pattern is irradiated with ultraviolet rays having an adequate wavelength, the CD of the resist pattern gradually decreases with time. The CD of the resist pattern can be controlled by applying the above results to the manufacture of a photomask. As a result, the pattern dimension of the light blocking layer and the phase shift layer formed on the photomask can be controlled.

FIGS. 6 to 8 show cross sectional views illustrating a method for manufacturing a photomask according to the invention.

Referring to FIG. 6, a material capable of shifting the phase of transmitted light, for example, a molybdenum silicon nitride (MoSiN) film is deposited on a transparent substrate 200 such as quartz to form a phase shift layer 202. Then, a material capable of blocking the transmitted light, for example, a chromium (Cr) film is deposited on the phase shift layer 202 to form a light blocking layer 204 having a specified thickness. Next, an electron beam resist 206 is coated on the light blocking layer 204. That is, a blank mask with the phase shift layer 202, the light blocking layer 204 and the electron beam resist 206 coated on the substrate 200 is prepared. Then, the resist 206 is exposed to an electron beam to form a specified pattern and the exposed resist 206 is developed and hardened to form a resist pattern. The light blocking layer 204 and the phase shift layer 202 are sequentially etched using the resist pattern as a mask.

Then, the CD of the resist pattern is measured to calculate the variation between the measured CD and the designed CD of the pattern. In this case, the variation between the measured CD and the designed CD of the resist pattern may differ according to the various mask regions. As shown in FIG. 9, the CD variation according to the mask regions may be represented as a map.

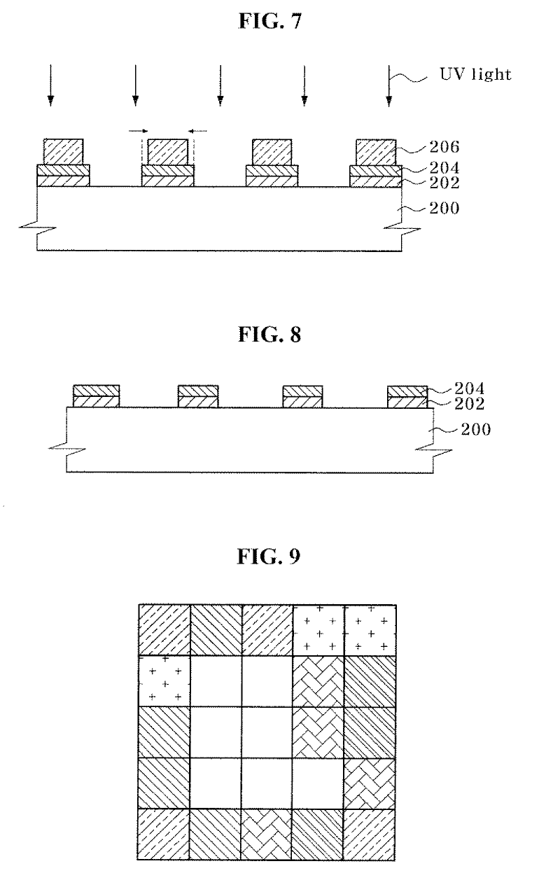

Referring to FIG. 7, the resist pattern of the resist 206 is irradiated with ultraviolet rays having a wavelength of about 172 nm for a predetermined time period. When the CD variation differs according to the various mask regions, the irradiation time with the ultraviolet rays may be set at different levels according to the various mask regions. For example, based on the map obtained in the previous step, if the CD variation of the resist pattern is large, the irradiation amount is increased by extending the irradiation time. On the other hand, if the CD variation of the resist pattern is small, the irradiation amount is decreased by shortening the irradiation time.

Referring to FIG. 8, the light blocking layer 204 and the phase shift layer 202 are sequentially etched using the CD-modified resist pattern of the resist 206 shown in FIG. 7 as a mask and, then, the resist 206 is removed. Thus, it is possible to form a phase shift mask with a modified pattern.

FIG. 9 shows a map representing the variation between the measured CD and the designed CD of the pattern according to the various mask regions. In FIG. 9, different patterns in the various mask regions represent different degrees of deviation between the measured CD and the designed CD. Likewise, two mask regions having the same pattern indicates that they have similar degrees of deviation between the measured CD and the designed CD. The amount of ultraviolet radiation is set differently according to the various mask regions to further improve the CD uniformity of the pattern.

As described above, in the method of manufacturing a photomask according to the invention, the resist is exposed to the electron beam, and then the light blocking layer and the phase shift layer are patterned using the resist pattern. Then, the CD of the resist pattern is measured to obtain the variation between the measured CD and the designed CD of the pattern. The CD of the resist pattern can be controlled by irradiating ultraviolet rays on the resist pattern according to the obtained variation. The light blocking layer and the phase shift layer are patterned using the CD-modified resist pattern, thereby improving the CD uniformity of the pattern formed on the photomask. Further, the uniformity of the pattern can be further improved by varying the irradiation amount of ultraviolet rays according to the various mask regions.

Although the preferred embodiments of the invention have been disclosed for illustrative purposes, those skilled in the art will appreciate that various modifications, additions and substitutions are possible, without departing from the scope and spirit of the invention as defined in the accompanying claims.

What is claimed is:

1. A method for manufacturing a photomask comprising the steps of:
forming a resist pattern on a substrate with a light blocking layer formed over the substrate;
etching the light blocking layer using the resist pattern as a mask;
measuring a critical dimension (CD) of the resist pattern;
irradiating ultraviolet rays on the resist pattern to modify the CD of the resist pattern, thereby forming a CD-modified resist pattern; and
etching the light blocking layer using the CD-modified resist pattern.

2. The method according to claim 1, wherein the step of measuring the critical dimension (CD) of the resist pattern comprises the steps of:
measuring the CD of the resist pattern in multiple mask regions of the resist pattern;
obtaining a variation between the measured CD and a designed CD of the resist pattern in the multiple mask regions; and
making a map of the resist pattern based on the obtained variation according to the multiple mask regions.

3. The method according to claim 2, wherein the step of irradiating ultraviolet rays on the resist pattern to modify the CD of the resist pattern comprises the step of:
varying an irradiation amount of the ultraviolet rays according to the multiple mask regions based on the map.

4. The method according to claim 1, wherein the step of irradiating ultraviolet rays on the resist pattern to modify the CD of the resist pattern comprises the step of:
irradiating the ultraviolet rays on the resist pattern until the CD of the resist pattern is equal to a designed CD of the resist pattern.
